(19) United States
(12) Patent Application Publication
(10) Pub. No.: US 2001/0050875 A1
(43) Pub. Date: Dec. 13, 2001

(54) Portable information capture devices

(76) Inventors: Richard Oliver Kahn, Austin, TX (US); Andrew Arthur Hunter, Bristol (GB)

Correspondence Address: Allan M. Lowe, c/o Lowe, Hauptman, Gopstein Gilman & Berner, Suite 310, 1700 Diagonal Road, Alexandria, VA, 22314, US

(21) Appl. No.: 09/788,669

(22) Filed: Feb. 21, 2001

(30) Foreign Application Priority Data
Feb. 21, 2000 (GB) 0004065.9

(51) Int. Cl. G11C 5/00

(52) U.S. Cl. 365/229

(57) ABSTRACT

PORTABLE INFORMATION CAPTURE DEVICES A portable information record capture device having: an information record capturer; a device memory adapted to have a library of stored information records; a controller adapted to evaluate the space available in the device memory and if the available space is insufficient, to accommodate a new information record to compress one of: either the new information record; or one or more of the pre-existing stored information records in the device memory to a size where there is freed-up enough device memory to accommodate the new information record, or its compressed form if the controller requires it to be compressed, the controller being adapted to record a new information record, or its compressed form if it is to be compressed, to the freed-up device memory. Each information record has an associated priority rating, and the controller is adapted to select which information records to compress and how far to compress them on the basis of the priority ratings of said information records. It is envisaged that such a device is especially suitable for digital video cameras and the like.

This invention relates to a portable information capture device, particularly, but not exclusively, digital cameras, and/or digital video recorders.

There are now many known portable information capture devices that have their own dedicated memory and which can be used to carry and present media files. Such devices include digital cameras, PDAs, etc. A large constraint of using these is the relatively small amount of memory that they are provided with. Generally, once the memory is full then information must be deleted before further information can be captured. Because the amount of memory provided on such portable devices is relatively small then it is filled relatively easily.

It is therefore, an object of one embodiment of this invention to try to alleviate this memory problem of such prior art information capture devices and/or to make better use of their memory.

The invention arose from a consideration of digital cameras, and whilst it is not limited to digital cameras it is helpful to consider the current digital camera art. At present a user attaches a removable digital memory unit (e.g. a memory card) to a digital camera and then takes pictures. A time comes when the memory is full and the user either has to attach a new removable digital memory unit or stop taking pictures until they have returned home and transferred the memory card to their PC to leave the card empty.

It is possible for a user of a digital camera to leave some (or all) images on the memory card when copying images to the PC. The user can then show other people the camera-stored images using the camera as a presentation device. However, when the user comes to take more pictures they then have to decide which stored image to delete to leave room for the new image that they wish to capture. Digital cameras have limited user interfaces at the time when a user has to delete a stored image from memory to make room for a soon-to-be-captured image. This is why most people simply choose to delete all images from the memory card when they transfer the images from the memory card to the PC. The work-flow process is for the user to note the memory is full; decide to capture a new image; determine how much memory is required for the desired new image; review existing camera stored images to decide which one (or ones) to delete; delete one or more images; capture new images; is off-putting to the user and is rarely performed. Most people simply note that their camera memory is full and “know” that they cannot take any more pictures.

According to a first aspect of the invention there is provided a method of operating a portable information capture device, having a device memory adapted to hold information comprising:

checking the available space within the device memory and if this is not enough to accommodate a new information record freeing further space within the device memory.

An advantage of this technique is that is removes the memory management requirement from a user and passes it to the capture device. This may make the device more easy to use.

The information record may be an image, or other multimedia information record.

The device memory may be freed by compressing or deleting information that is already contained therein (deleting may be viewed as an extreme form of compression). Clearly, this will free device memory as desired and allow new information to be entered into the memory.

In one embodiment the user is alerted to the fact that device memory must be freed before new information can be captured. The user may then be allowed manually to specify what information record (or records) contained in the device memory is to be deleted or compressed. This is advantageous because it gives the user control over what is to be degraded or deleted and what can be left in place; a user may have a favourite information record that they wish to keep unimpaired which the device will not be able to appreciate.

The method may include displaying information on a display means of the capture device. This is advantageous because it allows the code running on the capture device to keep a user informed as to the processes occurring. For example, the device may display a warning to the user that there is a danger of soon having to degrade existing information records in order to accommodate newly-captured information records, and/or a warning that such degradation is taking place. This may enable a user to decide to be reticent to acquire new information records.

The method may comprise holding the information in a capture buffer before it is moved to the device memory. This is advantageous because it allows information to be captured before the memory freeing process is started, allowing a user more control of how device memory is freed whilst allowing information capture.

Information displayed on the display means may include any of the following: free memory; size of information held in the capture buffer; size of pieces of information held in the memory; a representation of the information. The information may be given in absolute terms or as a fraction or percentage of the full memory capacity. It will be appreciated that the information held in the memory may be made up of a plurality of separate information items (a plurality of pictures, a plurality of songs, a plurality of video clips, or a combination of the foregoing, etc.). It is advantageous to display these information sizes because it is helpful if a user can see how much memory they must free (for example enough to cope with the size of information held in a capture buffer of the device). Further, it may be useful to display how far off a target free memory space the device is (free memory required to transfer the buffer memory into it). It may further be helpful if a user can see the size of information records so that they can work out which are the optimum information records to delete from the memory or degrade/compress. Of course, the device may evaluate this information automatically and either automatically make the choice for the user or give the use a suggested choice to be approved by the user. It is useful to display a representation of the information so that the user is reminded of the information and knows what they are deleting/compressing.

The user may be able to specify the level of compression to be applied to the information before it is stored in device memory. This is especially advantageous when the compression used is not loss-less because it gives the user control over the quality of the information stored in the device memory; clearly if the information record is important to the user they may want to keep a higher quality version than if the image (information record) is less important.

In another embodiment the capture device automatically deletes information already held in the device memory to allow further information to be stored in device memory. This can be advantageous because if the device automates the use of its memory the capture device may be simpler to use.

However, it removes or reduces the control that a user has over what information should be compressed or deleted. The user may be able to specify to the device whether or not information is to be compressed or deleted from the memory automatically, or by manual selection, or auto-selection subject to manual approval. Information records may be compressed or deleted based upon a rating, each record having a rating associated with it or a value from which a rating can be created. The priority rating associated with the information record may enable the device automatically to determine which records to delete or compress to accommodate a new record file. Alternatively, information may be deleted or compressed based upon the age of the information (which may be the sole rating criteria or may be part of the rating criteria).

The method may include the step of a user (or the device) assigning a priority rating to information that is about to be captured (or to newly captured information). This is especially advantageous in embodiments in which there is automated memory management because it will allow the code running on the capture device to make a decision as to which information record(s) to compress or delete (generally this will be the pieces on information with the lowest priority). It will be appreciated that if the information records held in the memory have all been captured by the device that each information record will therefore have a priority code associated with it if a user must assign such a code before the transfer of information to the device memory is completed.

In yet further alternative embodiments one or more information records held in the memory are compressed (rather than deleted entirely) to allow the newly captured information record to be stored. This may be in addition to, or instead of full deletion of one or more information records. This is advantageous because it will allow all of the information records within the memory to be maintained at least to some quality; the information content of a compressed information record will be reduced in quality but will still be there in essence.

The user may be able to specify which information record (or records) is to be compressed. This is advantageous because it gives the user more control of the handling of the information records. Different information records may be compressed to different degrees.

Code running on the capture device may automatically determine which information record should be compressed. This may occur automatically when it is apparent that there is not enough free memory to store the information being captured or present in the capture buffer. Code may determine the degree of compression necessary to accommodate the newly-captured record/piece of information.

A user may be able to configure the device to determine whether one or more information records are compressed automatically to allow information to be moved into the device memory, or whether the user can specify which information record should be compressed. The use of the display means discussed hereinbefore would be useful for manual selection of the information records to be compressed when they are images/visual information. When the information record comprises sound and/or video, the device may play a clip or extract to enable the user to recall what it is they are considering degrading.

If automatic selection is made information records may be compressed in turn, preferably starting with the information records with the lowest priority rating. This is again advantageous because it will allow favourite information records to be maintained at the highest possible quality until it is necessary to reduce the quality. Information held within the memory may have been compressed by a loss-less compression algorithm and therefore compressing the information further will probably result in a loss of quality. Thus, the method may initially store new information records as large, high quality files, and as memory becomes insufficient to capture new information records, the previously captured images (information records) may be automatically compressed to free memory for new information.

It will be appreciated that all information captured by the device, even at the highest quality, will generally be compressed using a loss-less compression algorithm before being stored in the device memory. Because the algorithm is loss-less there is no penalty to be paid by loss of information.

As an alternative to degrading only one, or some, pre-existing information records, the device may degrade all records, or all records of a certain class. In this way, a larger number of records can be degraded to a lesser extent than a single record or smaller number of records would have to be, to free-up the same device memory space. The user may be able to choose between these modes of degrading pre-existing records.

Newly captured information records may be stored at the highest available quality whilst there is still device memory available. When the device memory becomes full the device may free device memory in order to capture further information records. Further, the device may capture subsequent information at a lower quality thus using less device memory per information capture (or the user may be given the option to do this). This is advantageous for the following reasons: an amount of memory has a finite storage and will therefore be able to store a predetermined amount of information. If the quality of a particular piece of information (for example an image) is high then memory will be able to store fewer information records. As the quality of a particular information record is reduced the number of information records that can be stored will increase. A user may not know how many information records they are going to capture and therefore when a user first starts to capture information records the information records will be stored at high quality and when it becomes apparent that the user wants to store more information than the memory can handle at this level of quality the level of quality of pre-existing information records is reduced allowing further capture.

A user may be able to configure the device to determine whether information is compressed or deleted from the device memory. Indeed, some pieces of information may be deleted and some pieces of information may be compressed. It will be appreciated that the decision whether or not an information record should be deleted is of a personal nature to the user and may well depend on the importance the user attaches to the information record held in the capture buffer (or about to be captured); if the newly-captured information record held in the buffer/about to be captured is of great importance the user may be willing to sacrifice information that they had previously prioritised quite highly. However, they may prefer to heavily compress information before actually deleting it.

If compression is used the method may comprise successively compressing an information record with increasing compression levels until new information can be captured. The compression levels may be gradually increasing compression levels, for example there may be 5 or 10 or 50 compression levels to which an information record could be compressed. Preferably in such circumstances the compression algorithm used does not suffer from a degradation in quality because of fact that the final compression level is achieved by a plurality of compression steps. For instance if a number of compression algorithms are used to perform a compression in a first step to achieve a 20% compression and then in a second step this compressed image is compressed to take the total compression to 40% the quality will be lower than if a single compression is made to 40%.

However, a number of compression algorithms are known which do not suffer from this disadvantage. One such known algorithm is FLASHPIX™ wherein an information record is stored as successive levels of quality within the record, providing incremental progression. To reproduce the record at its full quality all of the levels must be used but to reproduce the record at its lowest quality only the lowest level need used. Using the FLASHPIX algorithm further compression requires the deletion of levels of quality above the desired quality level. Other suitable algorithms may be JPEG 2000, which provides a similar tiered compression scheme to FLASHPIX™ but produces smaller file sizes.

Indeed, the standard JPEG compression algorithm may be suitable if the image does not change, i.e. the boundaries of DCT blocks do not change, then little additional degradation results from multiple compression cycles upon the same image.

It is well-known for computers to have file systems that rely on folders and sub-folders therein to segregate information held on the computer's storage device. The method may comprise allowing the user to set up folders within the memory of the capture device. Such a method is advantageous because it will allow information to be logically stored and may make location and manipulation/selection of the information records more convenient and/or faster. As an example a folder could be set up in which newly-captured information records are stored (e.g. new information records not yet archived to a remote memory), a folder may be set up in which archived information records are stored (those that are already archived to a remote memory), and a folder may be set up in which favourite information records are stored. Sub-folders could, of course, be provided in any of these. For instance sub-folders could be set up in the newly-captured information records folder relating to the specific date on which the information records were captured.

Information capture devices such as digital cameras are well known and it is further known to have LCD screens associated with such devices upon which information held within the camera's memory can be displayed. However, generally the quality of image that can be displayed upon such a camera's screen will be much lower than can be displayed on other display media such as a computer monitor, etc. Therefore, the method may further comprise storing the information records in the device (e.g. camera) to the level of quality at which it can be reproduced on a reproduction means (e.g. display screen) of the capture device. (The reproduction means may be a display means to reproduce images or alphanumeric text, or may be a speaker means to reproduce sound). This is advantageous because it may allow for more information records to be held within the memory. The skilled person will appreciate that if it is desired to transfer the information records for reproduction at a later date on a device having a higher quality of output then it may not be satisfactory to restrict the quality of information contained in the stored information records in this manner. A user may be willing to sacrifice the quality at which they can reproduce information to allow them to hold more information records. The information record may be stored initially at a high quality and compressed later to make room for a newly-captured information record.

The method may store thumbnails, or other such summaries of the information, to allow a user to manipulate the information more easily. The thumbnails, or minimum information representative of the full information record, may be stored in addition to the full information records, or may be generated from them (or from higher-than-thumbnail versions of the information record).

The information may comprise any form of media (or what is commonly termed multi-media). For instance the information may comprise any one of the following: images, sound, video, text, holograms.

The device memory may be any form of memory and may comprise any one or more of the following: flash RAM cards, disc drives, RAM, etc.

Conveniently, the method comprises moving information into a buffer before it is moved into the device memory. This may allow information to be captured before device memory is freed. This is advantageous if the information to be captured is of a variable size and it is uncertain in advance just how much device memory needs to be freed.

Alternatively, the device memory may be freed before (e.g. just before) new information is captured, possibly as a new information record is captured (perhaps overwriting information already held within the device memory), or may occur pre-emptively. Pre-emptive memory freeing may free memory at intervals, or after an information record capture to ensure that there is enough device memory free for a further information record capture. The device may be arranged to maintain a predetermined memory space free for the acquisition of new information records.

In perhaps the most preferred embodiments the method comprises allowing the device memory to fill up to a predetermined threshold level and once this threshold has been reached freeing the device memory to allow further information to be captured and stored without exceeding the threshold level. An advantage of this method is that it will provided a buffer zone within the device memory (above the threshold) that will allow the further information to be stored. Generally, once the device memory has been filled to the threshold new information will be captured and placed into the device memory in the free space thus exceeding the threshold level and once the information capture has been completed memory is freed to return free device memory to the threshold value.

The space left free by using such a threshold level may allow a predetermined amount of new information to be stored. For instance if images are the new information the memory above the threshold may allow a number of images (for example 3) to be stored. This would give a user scope to take a number of images in quick succession and have those images stored before the device had to free memory. It will be appreciated that freeing device memory may be a “slow” process which takes a relatively large amount of processing time to accomplish and therefore not achievable quickly enough should the user decide to capture a number of information records in quick succession. Always maintaining space in device memory may help to alleviate this problem.

Conveniently the threshold amount of device memory that is kept free is adjustable. The adjustment may be by way of a user setting or may be by the device adjustment according to an algorithm. The algorithm conveniently adjusts the threshold according to the users use of the capture device. For instance if the user generally only takes a single information record at a time then the algorithm may maintain the buffer to be roughly the correct size for capturing a single record. However, if the user regularly captures a number of records in quick succession then the algorithm may maintain the enough memory free to hold the average number of records that the user captures (or the maximum number of records that a user has captured). Maintaining a part of memory free for immediate use and determining how large that free part is by monitoring historical use patterns of the device and setting the size of the free memory in accordance with the use pattern is considered to be attractive to the user since it does not require any input from them.

It is well-known to connect information capture devices to computers to allow information held on the capture device to be archived. For instance digital cameras can be connected to allow the pictures held within the camera to be stored on the computer and thus free the memory of the camera for further use. The same is true for video cameras, audio players, etc.

It is also known to provide reproduction devices (such as an MP3 player) that can be connected to computers to allow selective information to be reproduced by the reproduction device remote from the computer.

The method may further comprise allowing a user to specify which information records are transferred to a computer (computing means) to which the capture device is connected and thereafter deleted from the capture device. A user may not wish to delete all of the information records, preferring instead to maintain some records on the capture device for reproduction remote from the computer.

The method may allow the capture device to be connected to the computer by a number of techniques. Indeed, any one of the following may be applicable to the method: IRDA, USB, Fire Wire, any other wireless or wired communication protocol.

The method may automatically synchronise information maintained on the capture device and the home computer when the capture device is brought into range of the home computer. The skilled person will appreciate that the home computer need not be a computer as such but may be any device capable of communicating with the capture device, a television, a monitor, a video recorder, etc., and having a remote memory/having access to a remote memory. A user may initiate the automated procedure, may be by running appropriate code on the computer and/or device. Alternatively the capture device and the computer may automatically initiate the synchronisation when they are brought within a predetermined range of one another.

Preferably the method identifies the information records that have been transferred to the computer but also maintained on the capture device (i.e. archived). Such identification may be by the setting of a flag within data tables associated with the information records.

Alternatively, or additionally, the capture device may assign a number from a know series to an information record as it is captured and may further, record which information has been backed up on the computer by noting the number associated with the last piece of information transferred to the computer. Conveniently, the numbers assigned to the information are sequential. Alternatively, or additionally, the numbers may be the date and/or time at which the information record was captured providing convenient information which also provides the function of the number from a known series.

The methods of freeing memory space described hereinbefore (deletion or compression of information records) may act upon information records that are identified as being backed up in preference to those that have not been backed up. This is advantageous because even if the image (or other information record) is lost from the capture device there will be a copy of the information record to which the user can revert. The user may be able to set whether or not such backed up information records should be deleted in preference. Settings for each information record may be set differently. Preferably the display means of the capture device displays whether or not a piece of information has been archived. The display of this attribute is advantageous because it allows this fact to influence a user's decision as to which information record should be deleted.

The method may allow a user to transfer information records to the capture device from the device (possibly the computer) to which it is connected. The transferred information records may be stored in the device memory in the same manner as device-captured information records. The methods of allowing the memory to be freed in relation to newly captured information may also be used to allow transferred information records to be placed into the memory of the capture device.

The capture device used in this manner may be used as a portable reproduction device allowing a user to select information from a computer, transfer that information to the capture device in as best a manner as possible (through selective compression/deletion of information records in the capture device's memory) and reproduce that transferred information remote from the computer on which the information is stored.

As discussed hereinbefore it is possible to mark the information records with priority ratings or rankings to tell the capture device how important that information record is to a user. The method may further comprise the step of automatically determining this priority rating. For instance the capture device may assign a priority rating to each information record that it maintains. This priority rating may be updated. This is advantageous because the importance an information record is likely to change in a user's mind over time. It is likely that for the majority of pieces of information the importance of the information record will reduce as the information record ages. For example pictures of a recent holiday may well have a high priority when they are first taken but a lesser priority as time passes.

The method may base the priority rating upon the number of times an information record is reproduced/viewed. It is likely that an information record that is frequently reproduced has a high priority in a user's mind. Alternatively, or additionally, the method may base the priority rating on the number of times that an information record is transferred between the capture device and another device (perhaps a computer). Again, it is likely that an information record that is frequently, consciously, transferred will have a high importance.

Alternatively or additionally, the priority rating may be based upon the length of time for which an information record is reproduced. It will be appreciated that this will give an indication of the importance of the information record. For instance if the information record is an image and a user spends a lot of time looking at the image then it is likely that particular image is of high importance to the user. The priority rating may thus be increased as a user causes the associated information record to be reproduced. The algorithm may automatically decrement the priority rating with time.

A particularly suitable approach to allocation of priority rating is, or incorporates, the functional task or tasks that a user may wish to carry out with the information record. There may be separate priority ratings associated with separate compression levels. For example, it may be desirable to retain a certain information record at a resolution high enough for it to be printed, but important that the information record be at a sufficiently high resolution (but lower than the printing resolution) to allow it to be satisfactorily displayed on the device display. There may thus be a medium priority rating attached to retention at printing resolution, but a higher priority attached to retention at viewing resolution. If there is space pressure, the device will then compress the information record to viewing resolution, and only delete if there is additional space pressure (perhaps after deletion or compression of other records).

The method may use a specific information format that allows a priority rating to be maintained with information record. It will be appreciated that if an information record is removed from the capture device due to a transfer of information then the capture device will effectively lose the priority rating relating to that information record unless that information is maintained with the information record.

In some embodiments the method comprises combining two or more types of information. For instance the method may associate captured images with diary information, or address book information. This is advantageous because it can provide useful reminders to a user as to the significance of a date, or a reminder as to the identity of a person in his/her address book. The method may allow a library of pictures to be built up on the capture device, some of which are old and some of which are new.

It will be appreciated that portable capture devices generally have a means to reproduce information records held within the device memory thereof. This reproduction means generally cannot reproduce the information record to the quality at which it is stored. For instance the display screen on a digital camera generally cannot display an image to the quality that the camera can capture an image. Therefore, the method may comprise a user specifying what quality they wish to reproduce the information record. If the user only wishes to reproduce information at the quality that the capture device can reproduce then they may be satisfied to only store information at that quality; any higher quality being a waste of memory because it is superfluous. However, if the user wishes to reproduce the information record at a higher quality (perhaps in the case of a video camera on a television screen, etc.) then the method may store information records at a sufficient quality for that reproduction medium. Storing information records at a reduced quality may be applicable only to images that have been backed up. It will be appreciated that if there are further copies of the information record then it does not matter how the quality of the information record is affected but if the information record is the only copy then it may be important to try and maintain the quality of the record.

In some embodiments the method may be considered as freeing device memory of the capture device based upon priority ratings associated with information records held in the device memory. This freeing of device memory may be to accommodate freshly captured information records by the capture device, or may be to accommodate information records that are transferred to the capture device from a remote device such as a computer. Looking at the invention in this context the source of the information record is irrelevant.

According to a second aspect of the invention there is provided a method of reproducing information remote from a computing means upon which it is stored, the method comprising:

transmitting selected information to a portable information device upon which the information is stored;

causing the information device to reproduce the information when it is remote from the computing device;

wherein

information already residing on the information device is manipulated to allow information to be added from the computing means.

An advantage of such a method is that it provides a user with a portable device that allows the him/her to display information remote from the location where the information is archived.

The method may allow transmission of information by any suitable means between the information device and the computing means. For instance the information may be transmitted by a hard wired link between the computing means and the information device, a wireless link, a dial up connection, a network connection, etc.

The information device may be an information capture device that may allow information to be captured. For instance the information device may be a digital camera, a digital video camera, a Dictaphone, etc.

According to a third aspect of the invention there is provided a portable information capture device comprising:

a memory adapted to store information;

a capture means adapted to capture information;

a processing means adapted to control the transfer of information between the capture means and the memory; and

in use, the processing means being adapted to manipulate the information held in the memory to free space within the memory to allow newly captured information to be stored.

Such a device is advantageous because it allows a user to capture a greater number of information records than previously may have been possible; although these information records may be at a reduced level of quality. The apparatus should result in the user never (or perhaps rarely) being shown a “memory full” message. The device may always be able to acquire a new information record (e.g. take a new photograph), possibly at full information content/quality, but at the price of degrading existing information records.

The information capture device may be a digital camera, a digital video camera, a sound recorder, a means for capturing a hologram, etc. Indeed, the device may have a means for entering text which may be associated with any of the other types of media. Some of these devices may be more convenient than others because they have the capability of capturing more than one kind of media and may therefore prove more versatile.

In some embodiments the device may be a PDA or other portable information processing means and may be adapted to provide functions such as an address book or diary.

Preferably the information capture device further comprises a reproduction means that is adapted, in use, to reproduce information that is stored within the device. The reproduction means may comprise a screen, a speaker, etc. Such a reproduction means is convenient because it allows the information held within the memory to be reproduced.

Conveniently, the device comprises a display means (if the reproduction device is not a display means) adapted to convey information to a user. Such a display means may allow a user to set up the device, manipulate information held therein, etc.

The device may be adapted to connect to a base station that allows the device to be recharged and/or exchange information with another device.

The device is portable. Such portability may be defined in a number of different manners which include that the device is wearable, hand holdable, or pocketable. However, it may be convenient to define portability in terms of the weight of the device. The device may be roughly 2.5 Kg or below, it may be roughly 1.5 Kg or below, or indeed, it may be 0.5 Kg or below. It will be appreciated that the device could be any value in ranges defined between any of these weights.

According to a fourth aspect of the invention there is provided a portable information capture device according to the third aspect of the invention in combination with a base station adapted to receive the information capture device and allow information interchange and/or recharging of the information capture device.

The combination is advantageous because it may make the information capture device more convenient to use, and may make synchronisation of information/recharging of the device more convenient.

According to another aspect the invention comprises software which, when run on a digital camera controller, or an external computer, causes the digital camera to have its memory updated with pre-existing images.

Of course, the camera may also be used to display images that have been captured via its scene image capturer.

According to another aspect of the invention there is provided an information carrier carrying software adapted, in use, to cause a computer to perform the method as defined in any of the preceding aspects of the invention.

According to a further aspect of the invention there is provided an index device for display of remotely captured information records, comprising: a communications link for receiving information records captured at a remote information record capture device; a device memory adapted to store a plurality of information records; a controller adapted to evaluate space available in the device memory, and if sufficient space is not available for a newly received information record, to compress one or more of the information records such that sufficient space is available for the newly received information record; wherein each information record has an associated priority rating; whereby the controller is adapted to select which information records to compress and how far to compress them on the basis of the priority ratings of said information records.

There now follows by way of example a detailed description of the invention with reference to the accompanying drawings of which:

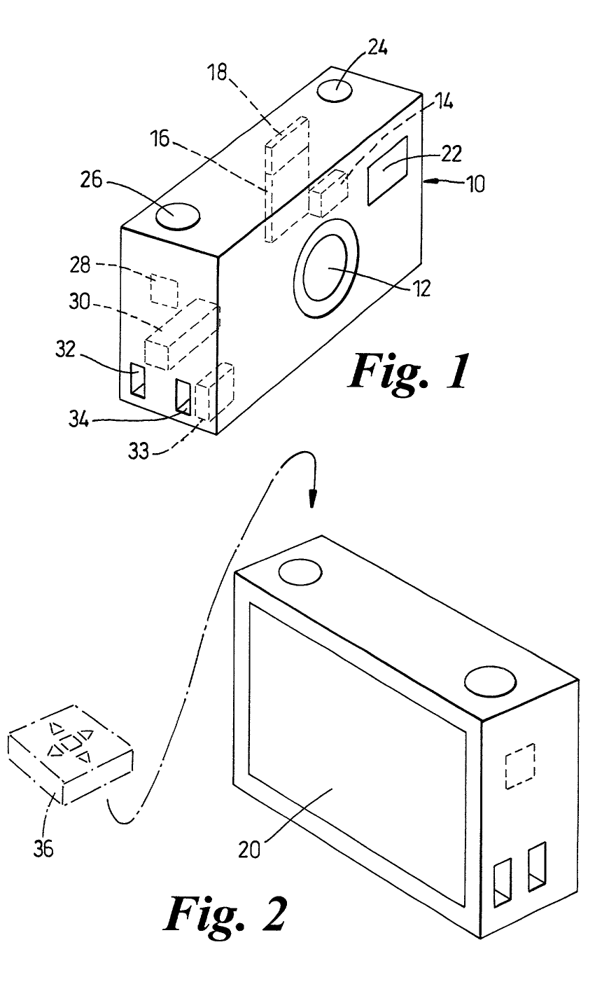

FIGS. 1 and 2 show schematically a digital camera in accordance with the invention;

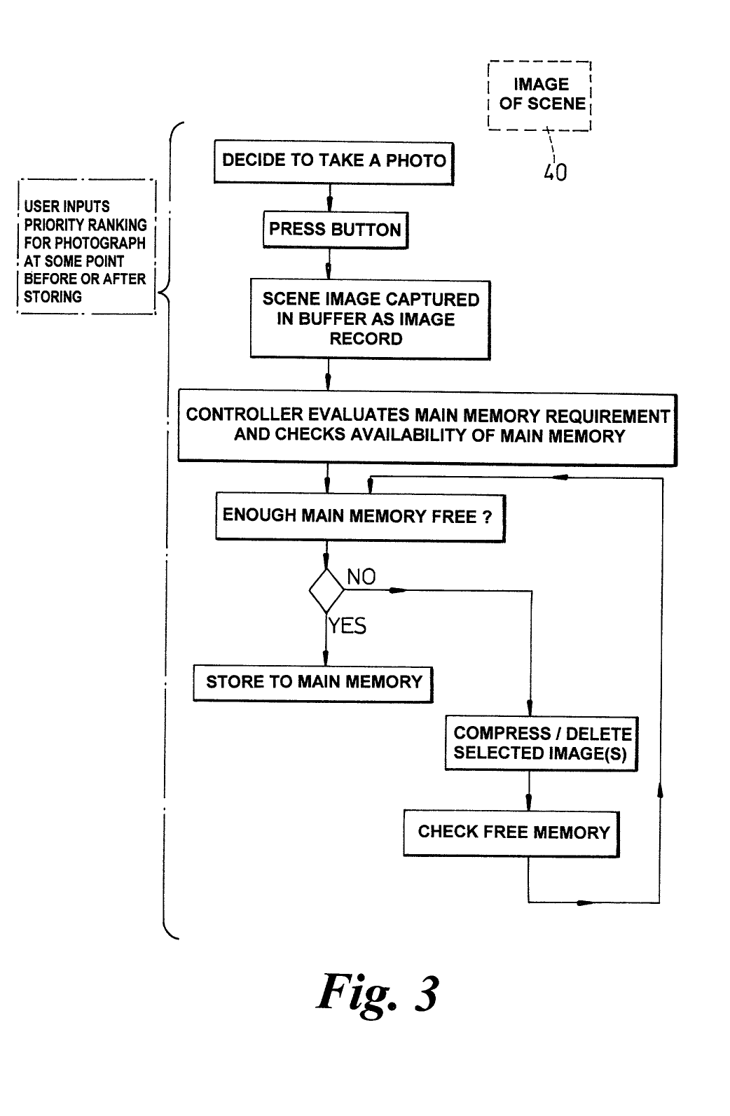

FIG. 3 shows a flow chart outlining the operation of the digital camera of FIGS. 1 and 2 running according to the present invention;

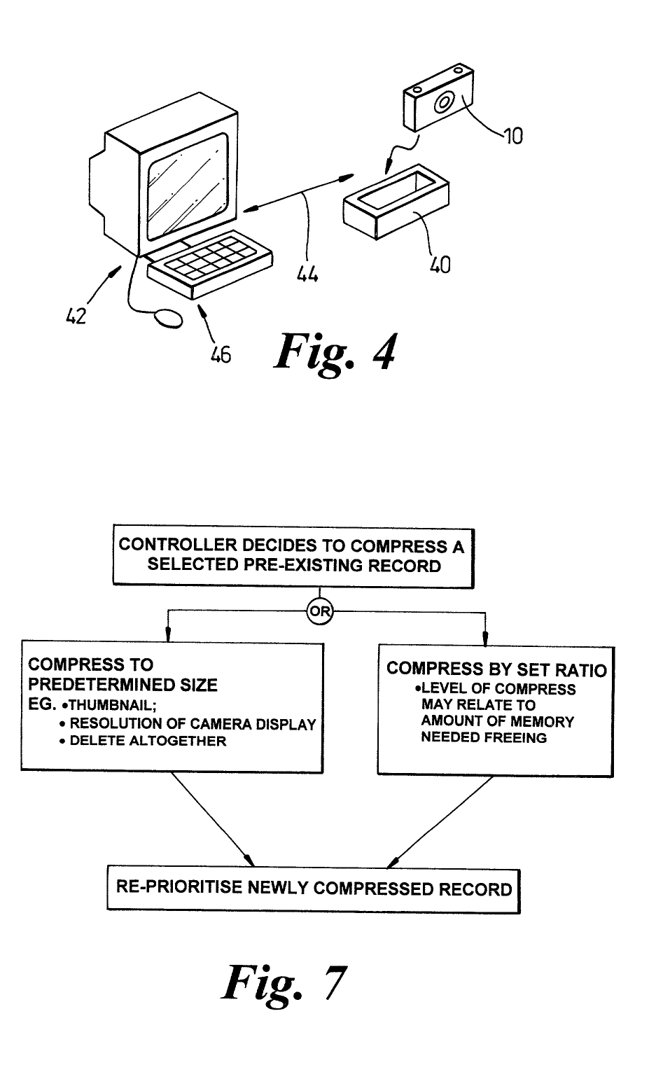

FIG. 4 shows schematically the communication of the camera of FIGS. 1 and 2 with a PC;

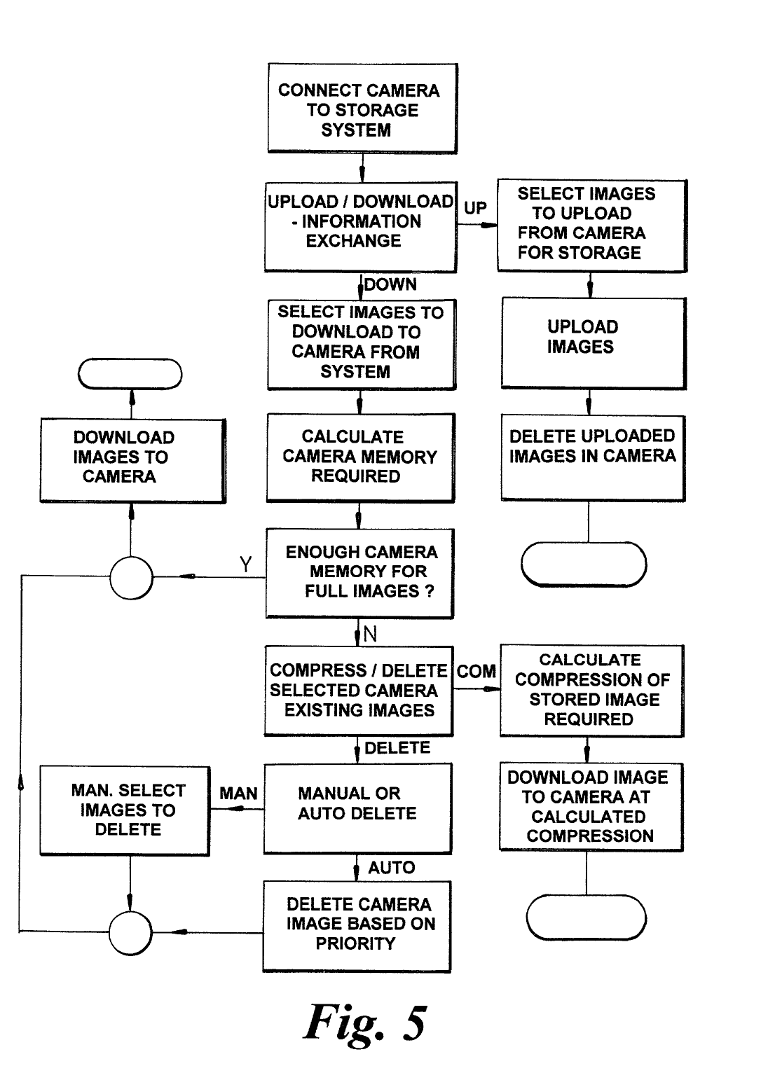

FIG. 5 shows a flow chart outlining a process according to the invention for connecting a portable information capture device to an archive device;

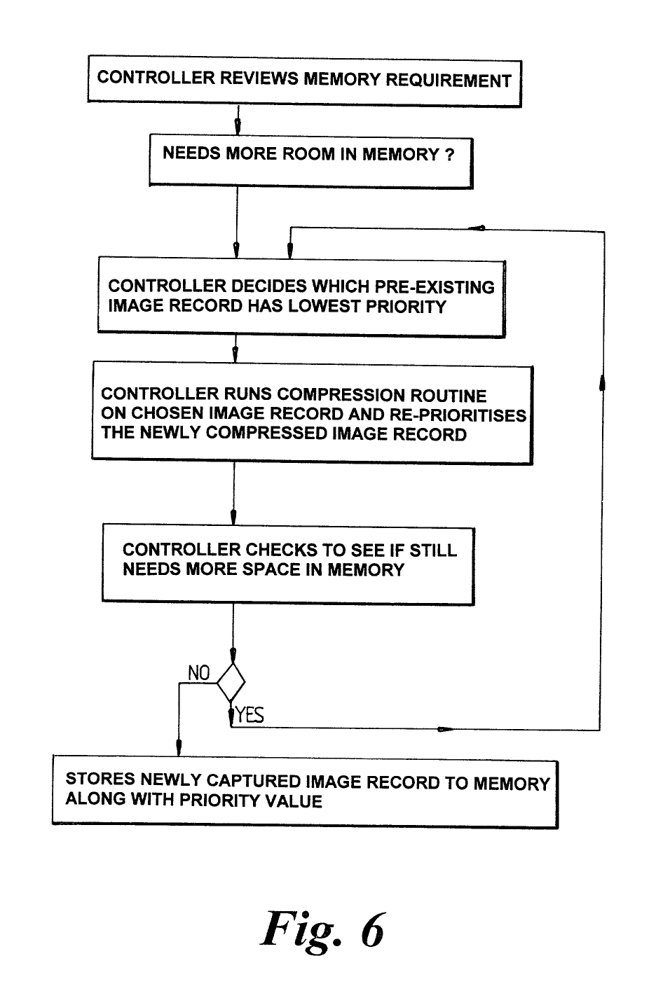

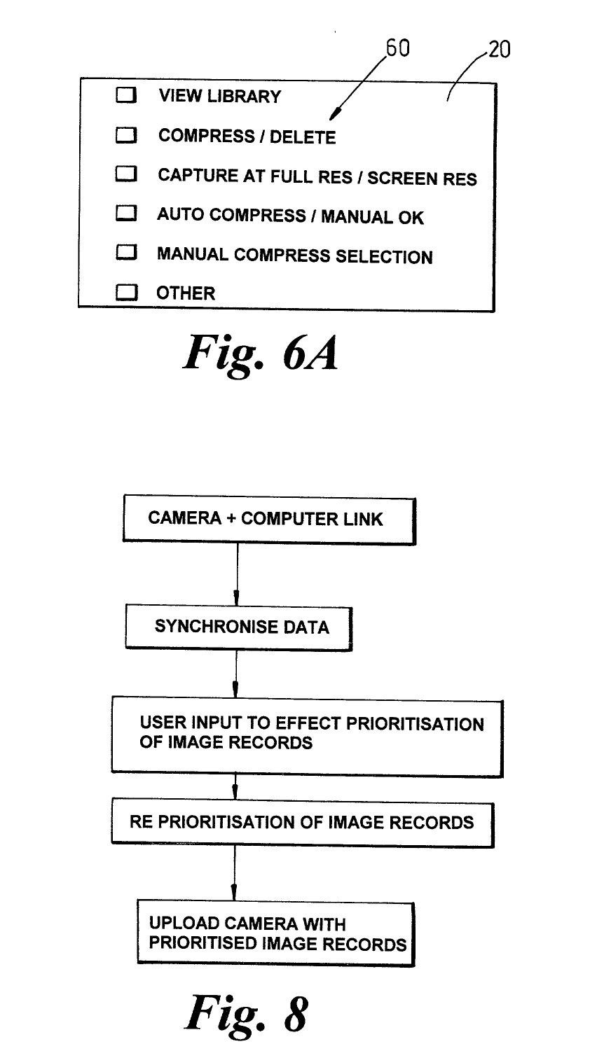

FIG. 6 shows an alternative flow chart outlining operation of the camera;

FIG. 6A shows a possible camera screen display;

FIG. 7 shows a flow chart for an algorithm deciding how to free camera memory;

FIG. 8 shows a possible flow chart for assigning a priority rating to information;

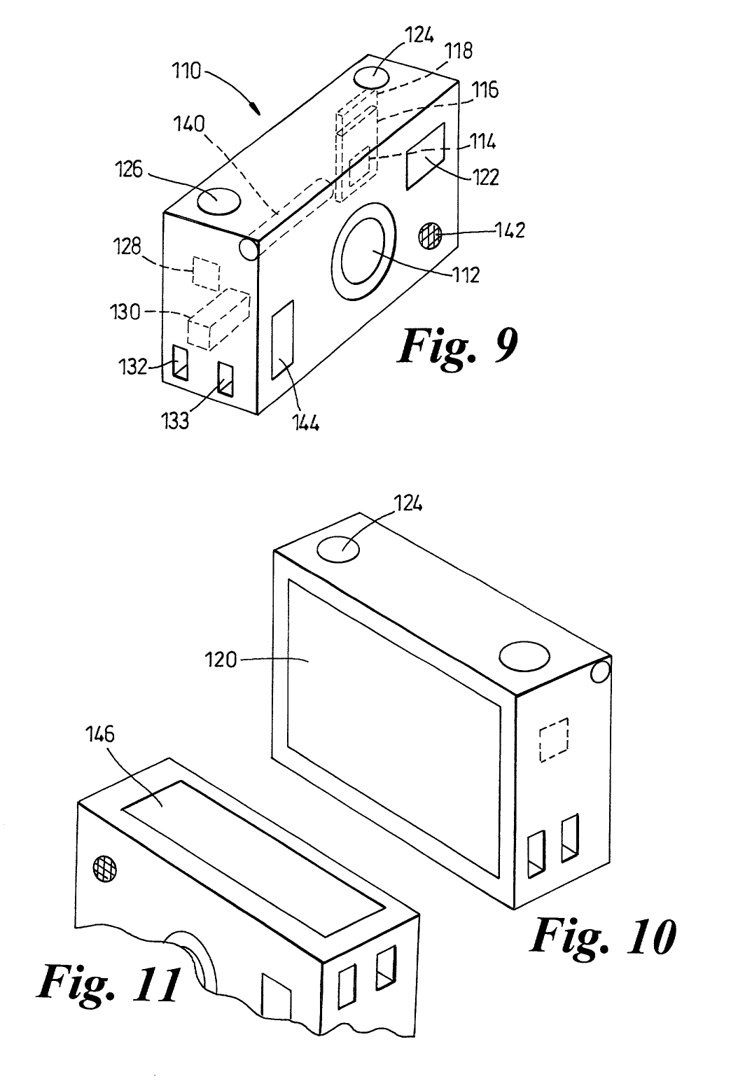

FIGS. 9 to 11 show schematically a further information capture device.; and

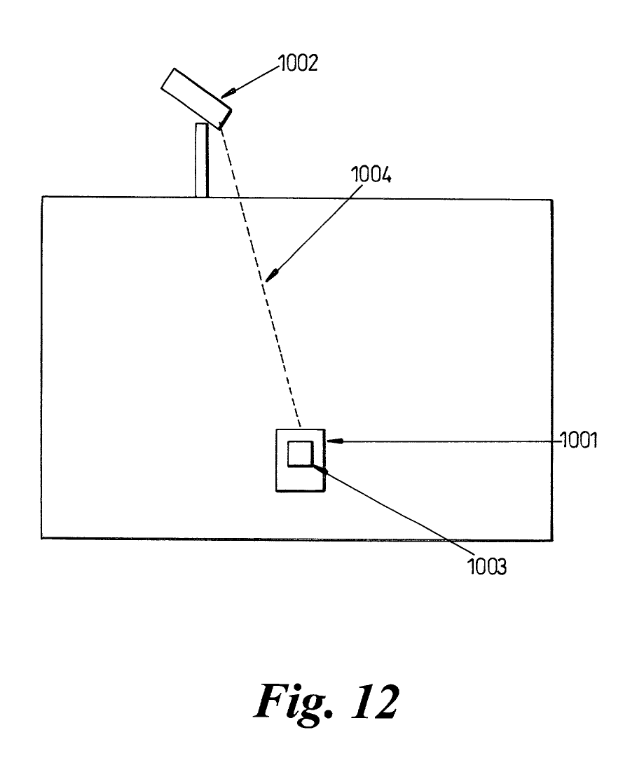

FIG. 12 shows an index device according to a further aspect of the invention.

FIGS. 1 and 2 show a digital camera 10 having a scene capturer 12 in the form of a photodetector array, equivalent to a lens of an optical camera; a control microprocessor 14, device memory 16, buffer memory 18, and a display 20 (e.g. LCD display). The camera also has a flash 22, an actuator button 24 which is pressed by a user to take a picture, a manually-operable control selection 26 adapted to select between different functions or processes performed by the camera, a port 28 adapted to receive a plug-in external memory unit (not shown), a battery 30 and battery recharging port 32, and a telecommunications port 34 adapted to communicate the microprocessor 14 with an external system.

It will be appreciated that the digital camera 10 may also be a digital video camera capable of capturing video rather that still images. For such a video camera a tape may be provided on which to store the video, or of course, video may be stored in a device memory in the same way as the still images.

FIG. 2 also shows an optional feature which only some versions of the camera 10 have, and that is a remote control 36 which may be removably attached to the camera and which may or may not be used to control some or all functions of the camera when it is attached to the camera (as well as being a remote control). The remote control 36 preferably communicates with the camera 10 via electromagnetic waves when it is remote. The remote control may also control a separate presenting device, such as a television (e.g. the camera may be linked to a television to display its pictures and the remote control may control the camera, and/or television).

It will be noted that the display 20 occupies, in this embodiment, substantially the whole of the back of the camera. The display 20 serves to display images stored in the camera memory 16 or 18, and as a viewfinder before a picture is taken.

FIG. 3 shows one possible flow diagram for capturing information according to the invention. This flow diagram will be described in relation to taking a picture using the digital camera of FIGS. 1 and 2 but it will be appreciated that other information could be captured with a different device. For instance, sound, video, a number of images in succession, telecommunications signals, or a hologram could be captured. Indeed, whilst a digital camera may be capable of capturing both sound and video the information capture device could be other than a camera and may be an audio player, a video recorder, etc.

The flow process starts when a user decides to capture a new image 40. The user presses the button 24 on the camera 10 and this causes the camera to take an image and store that image in the capture buffer memory 18. The size and quality of the image within the capture buffer 18 will depend on the settings that the user has specified (e.g. the resolution that has been selected and the number of colour levels will both affect the size and quality of the image). However, once the image has been captured the size of the image information record will be known or determinable by the control processor 14. (It will be appreciated that for a digital camera taking a single shot at known settings the size of the image file that is produced by taking the shot will be known before the shot it taken. However, for some types of media which span an indeterminate length of time (e.g. a video or sound clip) the size of the file is indeterminate until the information has been captured, and the controller/microprocessor may need to determine the newly-captured information record size).

Once the shot has been taken a controller, or processing means of the camera, the microprocessor 14, requires the user to enter a priority rating to be associated to the image that has just been captured by the camera. This priority rating is used by automatic device memory freeing processes as will be described hereinafter.

In FIG. 3 this step is indicated in chain-dotted line, since another embodiment does not require the user to input a priority rating at the time a photograph is taken, or at all. In another embodiment, the priority rating may be requested by the camera at any time before taking a new photograph and taking the next new photograph. A default priority rating may be attributed by the camera to the photograph if the user does not intervene. The priority rating is input using control 26.

After a priority rating has been entered the processor 14 determines whether or not there is enough free device memory within the device memory 16 to store the newly-captured image record stored in the buffer. If there is enough free memory the processor 14 causes the contents of the capture buffer 18 to be moved into the device memory 16 of the camera 10.

If however, there is not enough free device memory 16 the processor 14 ascertains how device memory 16 can be freed to allow the image record to be stored. The user can set whether this process is fully automatic or whether manual intervention is required by inputting instructions to the controller 14 via the input control 26.

Assuming that the user has specified that manual freeing of device memory is to be performed the user must then specify whether or not images are to be deleted from the device memory or whether the information contained in the device memory is to be compressed, again using input control 26.

If the user chooses to delete images (image records) from the device memory 18 they then specify which image records are to be deleted. The display 20 of the camera displays the file/memory size of the picture held in the capture buffer (i.e. the amount of memory that must be freed), the actual amount of device memory free, and the file size/memory of at least one selected image held in the device memory, along with an indication of what that image from device memory is (e.g. a thumbnail picture of it). The camera 10 displays on its display information relating to all stored image records (or at least a selection of them) to enable the user to make an informed choice as to which pre-existing stored image is to be deleted, and what effect that with have on the free memory of the camera. This information allows the user to decide the best strategy for deleting the images to free up space within the device memory 18. A thumb nail image may be displayed of images held in the device memory so that the user is reminded of images being considered for deletion. These thumbnail sketches may be displayed sequentially, or several (or all) at a time. It will be appreciated that the user will appreciate the personal importance of each pre-existing stored image record and the presence of particular “favourite” images may influence just which images are deleted.

If enough space is freed after an image has been deleted the newly-captured image record is moved from the capture buffer 16 into the device memory 18. If further free space is required the user is returned to a selection box asking if he/she wishes to manually or automatically free space.

Instead of deleting an image record the control microprocessor 14 can compress a pre-existing image record stored in device memory. If instead of selecting to delete images the user decides to compress images the user specifies that compression rather than deletion is required and specifies which files are to be compressed (using input 26). This compression may be from an uncompressed state to a compressed state, or it may be from a compressed state to a further compressed state. It will be appreciated that compressing the pre-existing image records results in a loss of image quality but that this may be acceptable to the user.

A compression algorithm is chosen that does not suffer from a loss of compression if a compression ratio is achieved in a number of steps. That is the final compressed image is of the same quality if a compression ratio of, say, 40% is achieved by two compression steps (for example first to 20% and then further compression to 40%) when compared to compression to 40% in one step. FLASHPIX, JPEG 2000, or standard JPEG algorithms may be suitable for this.

Once a pre-existing image record file has been compressed, free space in device memory is checked to ascertain whether there is enough space to move the contents of the capture buffer to the device memory. If this is the case the image in the capture buffer is moved. If this is not the case then the user is again required to stipulate whether or not they wish to perform manual or automatic freeing of device memory.

Of course, the camera microprocessor 14 may be configured to give the user the option of compressing the newly-captured image record temporarily stored in the buffer memory 18 before transferring it to device memory 16, reducing the device memory requirement to store it. However, it is envisaged that newly-captured image records that have not yet been archived (and are therefore only a copy of the image record known by the microprocessor to exist) would normally be stored at full quality if necessary at the expense of pre-existing image records.

If the user selects to allow the camera to automatically free device memory the processing means uses an algorithm to determine the best strategy for freeing the device memory. This algorithm uses the priority rating held in association with each image in the device memory to determine whether to delete images or to compress images, and to select which image or images are to be deleted or compressed. A user may be able to set weightings to influence the decision process made by the processing means.

For instance, if a number of images having low priority ratings are held within the device memory the processor may determine that it is acceptable to delete these. If there are a number of images having a high priority rating are held in the device memory then it is likely that the processor will not delete these but will instead further compress them. These decision may be based upon the priority rating that the user has assigned to the image that has just been captured. If the recently captured image has a higher priority rating than the images already in the device memory then the processor may give a higher priority to maintaining the quality of the just captured image.

If however, the recently captured image is assigned a priority rating that is lower than the images already maintained within the device memory 16 then the processor may compress the recently captured image rather than delete or degrade the quality of the images already in the device memory.

A user may, for example, be able to allocate a priority rating of 1-10 for any image, with 1 being the most important and 10 being the least important.

If the processor compresses the image records maintained in the device memory 18 a record is made of the overall compression that the image record has undergone. A threshold may be set beyond which the image cannot be compressed further. This threshold may be user definable. It will be appreciated that as an image is further compressed that its quality is reduced. Maintaining a record of the overall compression of the images prevents the images from being compressed to such an extent that they are worthless.

In one particular embodiment the priority rating assigned to the image records held within the device memory are variable and are altered by the processor based upon a further algorithm. It is likely that if the user keeps recalling an image record from the device memory for display on the display 20 that the image is of great importance to the user. Further, it is also likely that as an image record ages it is likely be become of less importance (as an example images of a recent holiday are important when the user has just returned from holiday but assume less of an importance as the holiday becomes more distant). Therefore, the processor may decrease the priority rating for a particular image if is not viewed for some time, or as time passes, and may increase the priority rating of an image if it is viewed frequently (and may increase the priority rating based upon the length of time that the information record is reproduced). Of course, it would be possible to simply delete or compress image records based upon the age of the image with the oldest being deleted or compressed first. This is a form of rating, and requires no input by the user to the rating process.

An option is given to the user to allow them to specify that some images have a fixed and unchangeable priority rating. This is likely to be applicable to images which are important to the user but that they do not wish to look at frequently (but have them present “just in case” they wish to view them). An example of such an image is perhaps of a close relative, or a pet.

The above process flow allows the digital camera 10 to be used as a portable display means that a user can carry with them to keep and view a collection of images. Further, it allows the pre-existing “favourite” images that may have been captured some time ago to be manipulated and degraded to allow the camera to capture new images but make the best use of the device memory 16.

The ability to use the camera 10 as a portable display of pre-existing images can be further enhanced when the connection of the camera to a remote memory or computing means such as PC is considered. Images may be transferred from the PC to the camera and stored in the cameras device memory for display remote from the computing means.

It will be appreciated that compression of information records can be a computationally intensive operation. Therefore, when information records are transferred between a remote memory and the device any compression/device manipulation that is required may be preferably performed on the remote device (if the remote device has a more powerful processor than the device). This compression/device manipulation may be to reduce the information record quality to that which the device is capable of reproducing.

In perhaps the preferred embodiment the camera 10 ensures that an amount of memory is always free to enable new information records to be captured. It will be appreciated that freeing device memory 16 may be a slow process which the camera may not be able to achieve fast enough to allow new information records to be captured and transferred to the device memory. Therefore, in this embodiment, the camera maintains a predetermined amount of free device memory 16. Once the device memory has been filled to above the predetermined or threshold level the controller frees device memory using the algorithms discussed hereinbefore. When a new information record is captured it is transferred to device memory and if this transfer fills the device memory above the threshold memory is again freed. The threshold may provide enough space to hold a single information record or may be a number of information records. It is perhaps convenient to provide enough free device memory to allow a number of records to be captured to make use of the device more convenient for a user.

The threshold level may be determined by an algorithm determined by the use patterns of a user. If the user only captures a single information record at a time the algorithm may set the threshold so that there is enough memory free to capture a single record. However, if the user regularly captures a number of records in quick succession then the algorithm may set the threshold to enable the average number of records to be transferred to the device memory (or may be the maximum number of records that have been captured in succession in the past).

Alternatively, the controller may keep a fixed amount of memory free, perhaps roughly 5 MB. This fixed amount of memory may be user determinable, or may be set by an algorithm as discussed above.

In another embodiment the device may free memory once an indication has been made that an information capture is about to occur. This indication may be by way of a user pressing the actuator button 26 or by focusing the camera 10 or by any other may that the device may be informed that capture is about to occur.

In some embodiments the camera 10 (or other capture device) stores multiple versions of the information record which are of differing qualities. There may for instance be a high quality image and a lower quality image which can be used as a thumbnail. In such embodiments when the controller has to free device memory the lower quality information records may be preferentially deleted over the high quality images. It will be appreciated that the thumbnails can always be reproduced from the high quality image as necessary.

FIG. 4 shows the camera 10 about to be plugged into a battery charger unit 40. The camera is in communication with a PC 42 automatically by the act of attaching it to the recharger 40. This could be via a wire link associated with the recharger, or via a wireless communication (referenced 44) between the camera or recharger (which may communicate with the camera) and the PC 42. The recharger 40 may have to be in the vicinity of the PC 42.

The same problems may occur when images are transferred to the camera as when new images are captured by the camera: there is a limited amount of camera memory and a decision on what to store in it needs to be made. This may be handled in same manner as when images are newly captured by the camera. That is to say that the user is given the choice to manually or automatically free device memory in the camera and can delete or compress images already maintained within the device memory 16 of the camera 10 in order to accommodate new images.

The user may input commands to control this process via the camera input control 26, or via a keyboard/mouse (or other PC input).

Also, in some embodiments this decision making process is controlled by the code running on the camera, whilst in other embodiments the process is controlled by code running on the computing means. That is the intelligence of the memory freeing may be distributed between the camera and the computing means.

The camera is provided with a connection means that allows the camera to be connected to the computing means. This connection means in this instance is an infra red link (referenced 33 in FIG. 1) but can be any other type of connection means (e.g. a cable connected to the camera via port 34). When the camera is placed into the vicinity of the computer 42 a link is automatically established between the camera and the computer. Image records in the camera memory that have not already been saved on a storage means of the computer (e.g. the hard drive) are automatically transferred to the PC, thus backing up that image. An archive bit associated with the image record in the camera's device memory is set to show that the image record has been backed up.

In an alternative embodiment an archive bit is not used to mark the images that have been backed up. Instead, the camera associates a sequential identifier with each of the image records maintained within its device memory and notes the number of the last image record that has been backed up. Then the next time that the information is synchronised with the PC only image records having a number greater than the previous last image to be backed up are backed up.

The archive bit is also used by the automatic memory freeing algorithms to determine the best strategy for freeing the device memory of the camera. Images that have not been backed up are usually to be considered more valuable than images that have been backed up; if an image has been backed up it is recoverable and therefore may be deletable in preference to an image record that has not been backed up.

As images are backed up on to the PC the user may be asked by the PC which image records should be transferred to his/her collection of favourite images stored in his camera device memory 16. This may be into the favourites folder of the operating system or elsewhere.

When a user is allowing the camera and the PC to synchronise information it may be convenient to charge the camera battery. Because there is an infra-red link between the PC and the camera the number of wires between the camera and the PC is greatly reduced.

Thus it will be appreciated that the camera (or other device) has its memory overwritten with new information, based on the priority rating preferences, after it has transferred its unarchived information to the remote memory unit (PC). Some or all of the information of the camera is replaced in the synchronisation operation.

In other embodiments, (or perhaps there is an option to make the following setting in the example above) the camera, when the user is taking photographs (or beforehand) automatically, without user input, deletes images from the camera's device memory to free space for newly-captured images (or images that are to be newly-captured). Such freeing may be by deletion or compression as discussed above and may occur just before a new image is captured (or indeed as a new image is captured allowing the old image to be overwritten), or may occur preemptively, either at intervals or after an image capture to ensure that space is available for subsequent captures. Using such methods it would be possible to operate without the previously described buffer in which newly-captured information is stored.

The control processor 14 of the camera may make a selection of preexisting image records to be compressed/deleted and may proceed to compress/delete them unless the user intervenes: thus the camera may have automatic memory-freeing without requiring a positive, conscious extra act by the user, but may have an override feature if the user wishes to make a final “yes/no” decision themselves as to what is to be degraded/deleted next, or the user may have a more active “perusal and positive selection” role as discussed earlier.

It will be appreciated that a camera's memory is able to store a finite amount of information and that therefore, the number of image records that can be stored is a function of the size of the image records. The size of an image record is dependent on its resolution, colour depth, and whether or not compression is used. When the camera is initially activated, with no image records in its memory, there will be a large amount of free memory and the camera may simply store newly acquired images at a high quality (so that fewer images can be stored in the device memory that if a lower quality were used). If the user only wishes to take a few images then there may be enough device memory so that all of the images can be stored at this quality.

However, it is possible that the user takes enough pictures so that the device memory becomes full. It is then possible to reduce the image quality of all of the images residing in the device memory to free space (either simultaneously/effectively simultaneously as perceived by the user, or sequentially as perceived by the user) and thus, allow the user to take more pictures. If the memory again becomes full the process can be repeated with the images in device memory having their quality reduced once more. This cycle may repeat until the quality cannot be further reduced. Of course, quality reduction may be by way of compression, compression factor, sampling rate, quantisation, reduction of frame rate, reduction of sampling rate, reduction of colour levels, reduction of resolution, etc. The device may compress, possibly sequentially, all of the archived information records before it degrades unarchived records. It may permit degradation of unarchived records in order to acquire yet further information records, or it may not.

This cycle removes the need for the user to select the quality at which they wish to take his/her images. Clearly, if he/she must decide at what quality the images are to be taken before they are taken they may wrongly estimate how many images are required and either take the images at a quality less than they could have done, or the camera may run out of memory. The camera may also be perceived by the user as “too awkward” to use if they have necessarily to make too many decisions when using the camera.

It will be appreciated that many digital cameras have an LCD panel to act as their display means. Generally, with present cameras this panel has a capability to display images at a much lower quality than that at which the camera can take new images. Therefore, if the camera is to be used as a portable display device, using this LCD panel, allowing images to be taken from a computing means and shown to third parties using the camera display, there is little point in storing the images at a higher quality than the LCD can display.

However, it would be possible to transport images on the camera and cause the camera to display the images maintained therein on a different display means, such as a television, monitor, etc. In such circumstances it may be worth maintaining image records in the camera memory of higher quality than the LCD panel can display. The user may be able to specify what display is to be used (or what quality of image record is required, e.g. high, medium, or low) and have the camera store the images at an appropriate quality. It is also possible to print directly from portable capture devices such as digital cameras where suitable protocols and communication mechanisms (such as IRDA) exist—in such cases the desirable quality level for information storage may be associated with printing at one or more specified resolutions.

As indicated above, it may be desirable to attach different priority levels to specified compression levels, and for these specified compression levels to be associated with different functional tasks. For example, it may be desirable for a high quality image to be stored for remote display or high resolution printing, but more important for a lower quality image to be stored for camera back display or low resolution printing (perhaps to allow a high resolution image to be obtained later). In this case, there may be a medium priority rating associated with “high resolution” storage and a higher priority associated with “low resolution” storage for the same information record. With such an arrangement, the record could be held at high resolution until it became lowest priority, at which point it would be compressed to lower resolution (or if a low resolution version already existed, deleted). This lower resolution version remaining would then be held until it became the lowest priority element (perhaps after compression or deletion of numerous other information records).

If media other than images is being captured other methods to reduce the amount of information may be applicable. For instance if the media is video then it may be appropriate to reduce the frame rate (which if taken to an extreme may reduce the information to one or more still images). Heavier compression is equally applicable.

In some embodiments captured information is associated with a different type of information. For instance a captured image/sound clip/video clip, etc. may be associated with an address book entry to remind the user of the identity of the person to which the address book entry relates. It may also be desirable to associate information with diary entries to provide prompts to a user as to the significance of the diary entry.

FIG. 6 shows an alternative routine for the camera microprocessor 14 assessing whether to compress or delete pre-existing image record files in its device memory 16 after acquiring a new image record in its buffer 18. In this example, the controller makes all of the decisions itself using allocated primary ratings for the image records, and compressing/deleting a record or group (sub-set) of records at a time until there is sufficient space. From a knowledge of the file size of the newly-captured image record and the file sizes of the existing image records, the controller can use algorithms to determine which one (or more than one) pre-existing image record to degrade (or indeed delete), and by how much.

FIG. 6A shows a screen 60 displayed on the camera display 20 to the user, giving the user the choice of what mode of operation to put the camera into (input via the button 26).

FIG. 7 shows an example of a compression decision routine. The processor may be programmed to choose a information record for compression, and this either compresses it to a selected one of a finite predetermined set of sizes (e.g. minimum resolution thumbnail, or to quality of camera display, or to delete altogether), or it may operate on the selected image record with a compression routine that compresses by a ratio. The ratio may be one of a predetermined finite set of ratios (e.g. 25%, 50%, 75%, 100%), or the controller may evaluate how much compression is needed to free-up the required amount of memory and compress to that level.

FIG. 8 illustrates the possibility of the user inputting priority rating-effecting inputs to the computer 42 or camera 10 at some time before the camera is removed from the vicinity of the PC and is used independently (ether before linking, or whilst linked). For example, the user may type into the computer, in an appropriate field, “PROJECT EXCALIBUR”, and “AUNTIE MABEL”. The computer-stored main library of image record should have associated them with tags and references, and this would result in those records having the same, or a linked, tag being temporarily repriority ranked for the purpose of that particular transferring operation. The camera would then, for example, have in its memory images relating to PROJECT EXALIBUR (for a work meeting), and images relating to AUNTIE MABEL (for a personal visit to see her). It may, of course, be necessary to allocate tags to images in the PC memory and to set up appropriate links between tags/hierarchies of tags.

Priority ratings may be assigned on a folder/sub-folder basis. Any information record in a particular folder may be assigned a particular rating, or influence a rating algorithm by an equal amount.

FIGS. 9 to 11 illustrate another digital camera 110, although “digital multimedia device” may be amore appropriate term, since it is far more than a camera. The device has an image capturer 112, a controller 114, a device memory 116, a buffer memory 118, a display 120, a flash 122, a photograph/video actuator button 124, a user-operable input interface 126, a port 128 for extra memory, a battery 130, a recharging socket 132, and a wireless telecommunication link 133. These are similar to features on the camera 10.

In addition, the device 110 is a mobile telephone and has an aerial 140 (which may be extendible), a microphone 142, and a speaker 144. The display 120 also serves as an input mechanism for telephone numbers (it can display a grid of telephone numbers and characters and pseudo buttons and detect when a user indicates one by touching it with their finger).

The device 110 also serves as a tape recorder/Dictaphone using the microphone 142 (and the speaker 144 for playback). It records the sound to the memory 118, then to memory 116 if there is room/makes room in memory 116. The device may also be used to record telephone calls using memory 116, 118.

The device 110 also serves as a video camera/video display, using the display 120 and microphone 142 and speaker 144 (and of course memory 116, 118).

The device also has a scanner, referenced 146, and OCR software. It also have voice recognition software for turning dictation into a word-processable document, and for controlling its functions (in addition to, or instead of, manually-input commands).

The device 110 also serves as a music or sound player, with pre-recorded songs (for example) being stored in the memory.

As will be appreciated, the invention applied to visual image records can be applied to information representing sound, or video, or text (e.g. ASCII documents), or any multimedia.

The device 110 may have more, or fewer functions and features and need not, of course, necessarily have a camera facility.

It should be noted that aspects of the invention can be employed by a device which is not, strictly, an information capture device. In particular, it is relevant to a display device for representation of images captured elsewhere—an index device. This arrangement is shown in FIG. 12. Such an index device 1001 may, for example, hold images obtained at a known rate over a communications link 1004 from a remote location (such as a rooftop camera 1002) for display on a display 1003. Particular priority rules could apply to retention of information records on such a device. These may, for example, be set according to predetermined criteria as to image content or time of capture. It may also be acceptable for index records to be progressively compressed over a given time interval, or until the index device is reset by a user.

1. A portable information record capture device having:
an information record capture mechanism;
a device memory adapted to store a plurality of information records;
a controller adapted to evaluate space available in the device memory, and if sufficient space is not available for a newly captured information record, to compress one or more of the information records such that sufficient space is available for the newly captured information record;
wherein each information record has an associated priority rating; whereby the controller is adapted to select which information records to compress and how far to compress them on the basis of the priority ratings of said information records.

2. A portable information record capture device as claimed in claim 1, wherein one, but not the only, option available for compression of a information record is deletion of the information record.

3. A portable information record capture device as claimed in claim 1, wherein said priority rating includes predefined permissible compression levels for an information record.

4. A portable information record capture device as claimed in claim 3, wherein said predefined permissible compression levels are defined to be suitable for defined functional purposes.

5. A portable information record capture device as claimed in claim 4, wherein the portable information record capture device is a camera and one defined functional level is suitability for printing at a predetermined resolution.

6. A portable information record capture device as claimed in claim 4, wherein the portable information record capture device is a camera and one defined functional level is suitability for viewing at the resolution of a display of the camera.

7. A portable information record capture device as claimed in claim 1, wherein said priority rating includes an indication of whether or not an information record is stored elsewhere.

8. A portable information record capture device as claimed in claim 7, wherein deletion of an information record in compression by the controller is only permissible if the information record is stored elsewhere.

9. A portable information record capture device as claimed in claim 1, further comprising an interface for downloading information records from a remote source of information records.

10. A portable information record capture device as claimed in claim 9, wherein deletion of an information record in compression by the controller is only permissible if the information record is a downloaded information record.

11. A portable information record capture device as claimed in claim 9, wherein said priority rating includes predefined permissible compression levels for an information record.

12. A portable information record capture device as claimed in claim 11, wherein said predefined permissible compression levels are defined to be suitable for defined functional purposes.

13. A portable information record capture device as claimed in claim 1, wherein an available priority rating for an information record is that the information record is not compressable.

14. A portable information record capture device as claimed in claim 1, further comprising a user interface whereby a user can determine a priority rating for an information record.

15. A portable information record capture device as claimed in claim 1, whereby a class of information records may be given a common priority rating.

16. An index device for display of remotely captured information records, comprising:
a communications link for receiving information records captured at a remote information record capture device;
a device memory adapted to store a plurality of information records;
a controller adapted to evaluate space available in the device memory, and if sufficient space is not available for a newly received information record, to compress one or more of the information records such that sufficient space is available for the newly received information record;
wherein each information record has an associated priority rating; whereby the controller is adapted to select which information records to compress and how far to compress them on the basis of the priority ratings of said information records.

17. An index device as claimed in claim 16, wherein the priority rating of a newly received information record is calculated by the controller according to predetermined criteria.
